(19) United States
(12) Patent Application Publication
(10) Pub. No.: US 2004/0027030 A1
(43) Pub. Date: Feb. 12, 2004

(54) Manufacturing film bulk acoustic resonator filters

(76) Inventors: Li-Peng Wang, Santa Clara, CA (US); Eyal Bar-Sadeh, Jerusalem (IL); Valluri Rao, Saratoga, CA (US); John Heck, Mountain View, CA (US); Qing Ma, San Jose, CA (US); Quan Tran, San Jose, CA (US); Alexander Talalyevsky, Jerusalem (IL); Eyal Ginsburg, Tel-Aviv (IL)

Correspondence Address: Timothy N. Trop, TROP, PRUNER & HU, P.C., STE 100, 8554 KATY FWY, HOUSTON, TX, 77024-1841, US

(21) Appl. No.: 10/215,407

(22) Filed: Aug. 8, 2002

(51) Int. Cl. H03H 9/205

(52) U.S. Cl. 310/311

(57) ABSTRACT

A film bulk acoustic resonator filter may be formed with a plurality of interconnected series and shunt film bulk acoustic resonators formed on the same membrane. Each of the film bulk acoustic resonators may be formed from a common lower conductive layer which is defined to form the bottom electrode of each film bulk acoustic resonator. A common top conductive layer may be defined to form each top electrode of each film bulk acoustic resonator. A common piezoelectric film layer, that may or may not be patterned, forms a continuous or discontinuous film.

### BACKGROUND

This invention relates to film bulk acoustic resonator filters.

A conventional film bulk acoustic resonator filter includes two sets of film bulk acoustic resonators to achieve a desired filter response. All of the series film bulk acoustic resonators have the same frequency and the shunt film bulk acoustic resonators have another frequency. The active device area of each film bulk acoustic resonator is controlled by the overlapping area of top and bottom electrodes, piezoelectric film, and backside cavity.

The backside cavity of a film bulk acoustic resonator is normally etched by crystal orientation-dependent etching, such as potassium hydroxide (KOH) or ethylenediamene pyrocatecol (EDP). As a result, the angle of sidewall sloping is approximately 54.7 degrees on each side. When a filter is made up of a plurality of series and shunt FBARs, each having a backside cavity with sloping sidewalls, the size of the filter may be significant.

Thus, there is a need for better ways to make film bulk acoustic resonator filters.

### BRIEF DESCRIPTION OF THE DRAWINGS

FIG. 1 is top plan view of a film bulk acoustic resonator filter in accordance with one embodiment of the present invention;

FIG. 2 is a cross-sectional view taken generally along the line 2-2 at an early stage of manufacturing the embodiment shown in FIG. 1 in accordance with one embodiment of the present invention;

FIG. 3 shows a subsequent stage of manufacturing in accordance with one embodiment of the present invention;

FIG. 4 shows a subsequent stage in accordance with one embodiment of the present invention;

FIG. 5 shows a subsequent stage in accordance with one embodiment of the present invention;

FIG. 6 shows a subsequent stage in accordance with one embodiment of the present invention;

FIG. 7 shows a subsequent stage in accordance with one embodiment of the present invention;

FIG. 8 shows a subsequent stage in accordance with one embodiment of the present invention; and

FIG. 9 shows a subsequent stage in accordance with one embodiment of the present invention.

### DETAILED DESCRIPTION

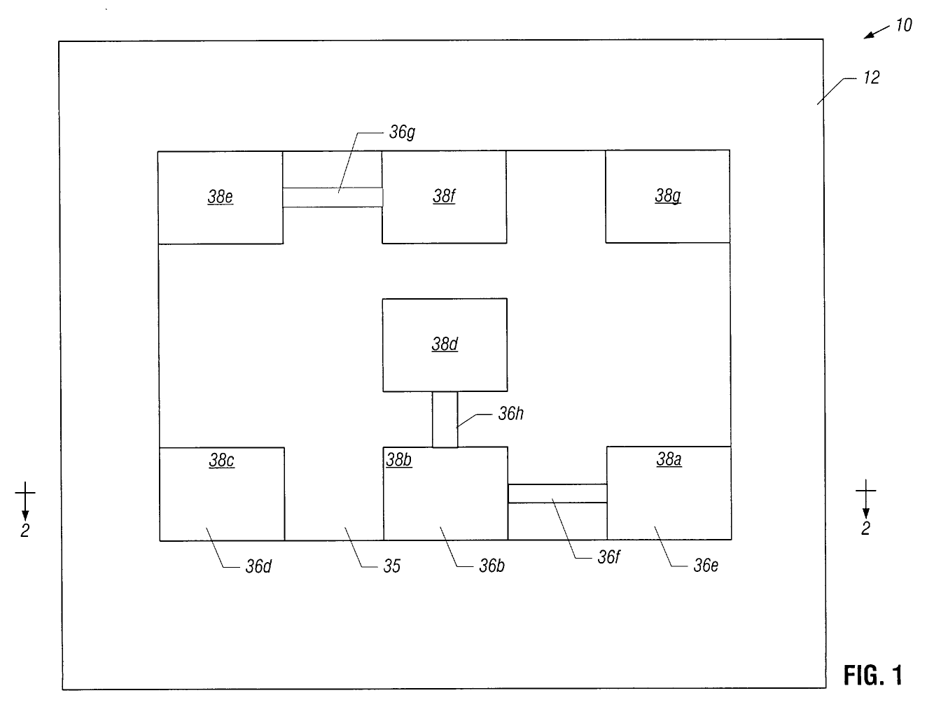

Referring to FIG. 1, a film bulk acoustic resonator (FBAR) filter 10 may include a plurality of film bulk acoustic resonators 38 having top electrodes 36. The FBARS 38c and 38a are shunt FBARs while the FBAR 38b is a series FBAR coupled to the FBAR 38a via an extension 36f of the upper electrodes 36b and 36e.

The intermediate layer in each FBAR 38 includes a piezoelectric film. In one embodiment, the same layer of piezoelectric film may be positioned underneath each of the upper electrodes 36 of the FBARs 38. Thus, in one embodiment, the material 35 may be a piezoelectric film. In another embodiment, the material 35 may include an interlayer dielectric (ILD) that fills the area between FBARs 38 while the region under each upper electrode 36 is a piezoelectric film.

In one embodiment, the active area of each FBAR 38 is controlled by the extent of overlapping between the upper electrode 36 and the underlying piezoelectric film, as well as the lowermost or bottom electrode. In some embodiments all of the FBARs 38 are effectively coupled through a single membrane, be it a continuous piezoelectric film or a layer that includes regions of piezoelectric film separated by an interlayer dielectric.

In some embodiments, strengthening strips may be used to improve the mechanical strength of the overall filter 10. The strengthening strips may be designed in any of a variety of shapes.

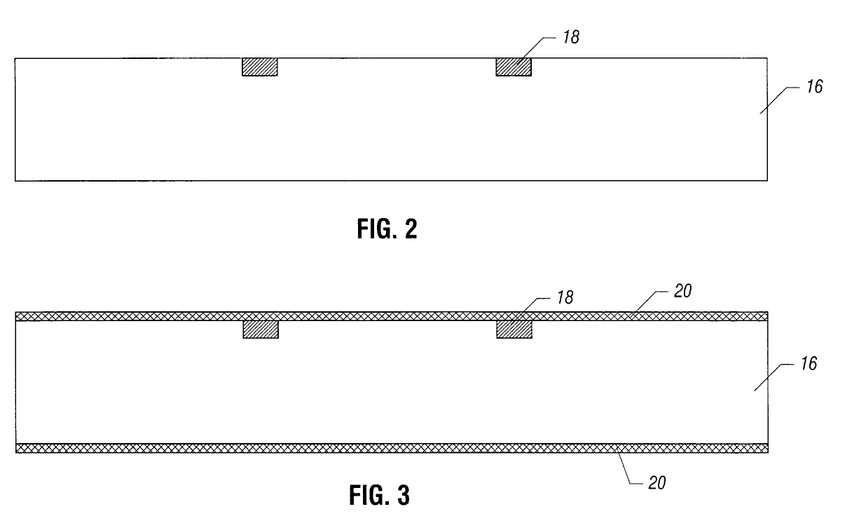

Referring to FIG. 2, the initial fabrication begins by forming the ion implanted regions 18 in one embodiment of the present invention. The ion implanted regions 18 eventually become the strengthening strips in one embodiment of the present invention. The ion implant may be, for example, oxygen or heavy boron, using a heavy boron etch-stop method. Then a rapid thermal anneal may be utilized to activate the doping. Cascade implantation may be used in some embodiments to achieve a uniform profile. In some embodiments the thickness of the implanted and annealed region is about 6 micrometers.

Next, an insulating layer 20 may be deposited on the top and bottom surfaces of the substrate 16. In one embodiment, the layer 20 may be formed of silicon nitride that acts as an etch stop layer and a backside etching mask.

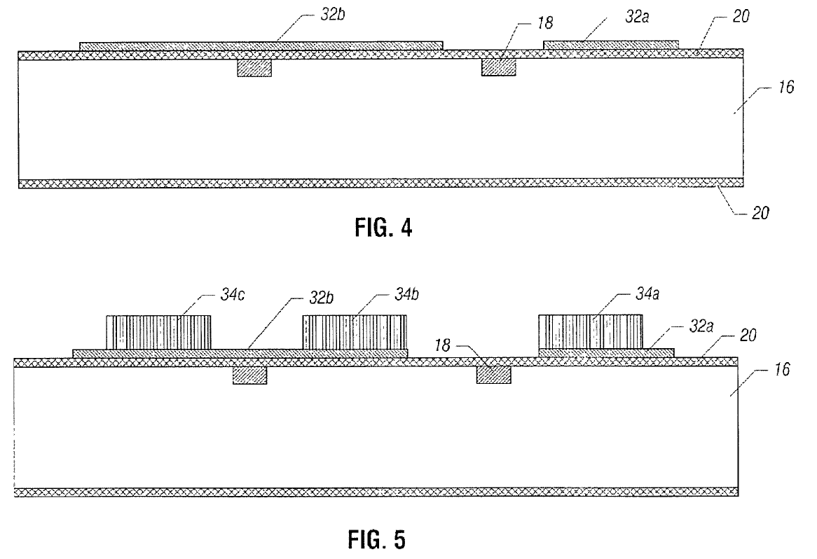

Turning next to FIG. 4, the bottom electrodes 32 may be defined by deposition and patterning in one embodiment of the present invention. Next, as shown in FIG. 5, the piezoelectric layer 34 may be deposited and patterned over the bottom electrodes 32 in one embodiment of the present invention. In another embodiment, a continuous piezoelectric film may be utilized.

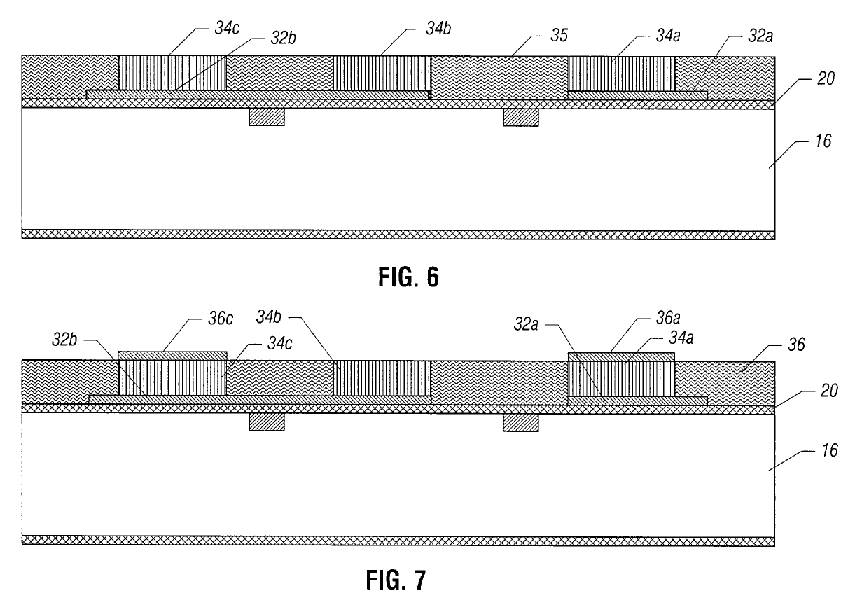

Referring to FIG. 6, an interlayer dielectric 35 may be deposited between the piezoelectric layer 34 sections such as the sections 34a and 34b. Chemical mechanical polishing may be used to cause the upper surface of the interlayer dielectric 35 to be co-planar with the upper surface of each piezoelectric layer 34 section.

Turning next to FIG. 7, the upper electrodes 36a and 36c for the shunt FBARs 38a and 38c may be deposited. Thus, referring to FIG. 1, each of the electrodes 38 is a generally rectangular section in one embodiment. Any necessary vias may be etched at this time.

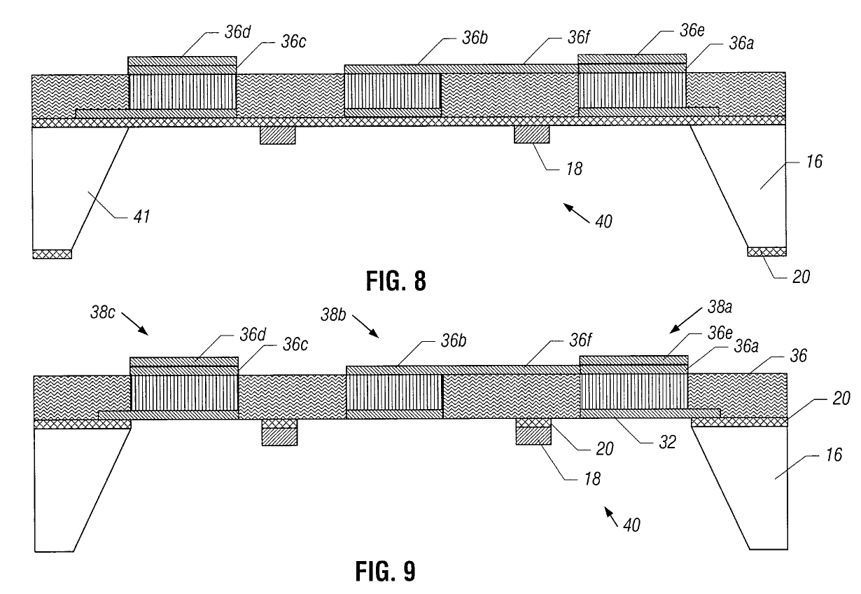

Referring to FIG. 8, the backside etch may be utilized to form the backside cavity 40 with sloping sidewalls 41. The initial etch may not extend through the lowermost insulator film 20 in one embodiment. Thereafter, a bulk silicon etch may be utilized to form the cavity 40 through the substrate 16. The implanted regions 18 remain after this etching because the etchant is selective of bulk silicon compared to doped silicon. Suitable etchants include KOH and EDP.

By having all of the FBARs 38 on the same membrane the overall size of the filter 10 may be reduced. For example, only one backside cavity 40 may be used for a number of FBARs 38, resulting in a more compact layout made up of FBARs that may be closely situated to one another. In some embodiments, portions of the interlayer dielectric 35 near the outer edges of the filter 10 may be removed to achieve the structure shown in FIG. 1.

The electrodes 36b, 36f, 36d, and 36e may be deposited. The electrode 36b acts as the upper electrode of the series FBAR 38b in this example. The electrodes 36d and 36e may be added to differentiate the frequency of the shunt FBARs 38a and 38c from the frequency of the series FBAR 38b. The electrode 36f acts to couple the FBARs 38b and 38a through their upper electrodes. However, the electrodes 36d, 36b, 36f, and 36e may be added in the same step in one embodiment.

As shown in FIG. 9, the layer 20 may be etched to complete the formation of the strengthening strips in the backside cavity 40. In some embodiments the strengthening strips may be arranged in a # shape with two parallel strengthening strips arranged generally transversely to two other parallel strengthening strips. However, a variety of configurations of strengthening strips may be used in various embodiments.

The filter 10, shown in FIG. 1, has all series and shunt FBARs in one cavity 40 and the active area of each FBAR is controlled by the overlapping area. The strips of implanted regions 18 may act as strengthening strips to improve the mechanical strength of the entire structure.

In accordance with other embodiments of the present invention, the strengthening strips may be formed by etching trenches in the substrate 16 and filling those trenches with an insulator such as low pressure chemical vapor deposited silicon nitride. The trenches may then be filled to form the strengthening strips.

By making a more compact design, with shorter traces such as electrodes 36f, 36h, and 36g, insertion loss and pass-to-stop band roll-off may be improved in some embodiments.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a plurality of film bulk acoustic resonators on the same substrate; and
forming an upper electrode from a single conductive layer, said upper electrode being positioned over each film bulk acoustic resonator.

2. The method of claim 1 wherein forming a plurality of bulk acoustic resonators includes forming a plurality of series connected film bulk acoustic resonators on the same substrate coupled by at least one shunt film bulk acoustic resonator.

3. The method of claim 1 including forming a strengthening strip across said substrate to strengthen said substrate.

4. The method of claim 3 including forming at least two parallel strengthening strips.

5. The method of claim 3 including forming a strengthening strip by implanting a region across said substrate.

6. The method of claim 5 including implanting a strip using a species selected from the group consisting of boron and oxygen.

7. The method of claim 1 including forming bulk acoustic resonators by using a backside etch to etch away the backside of said substrate and to form a backside cavity.

8. The method of claim 7 including using an etchant which does not etch away a strengthening strip formed in said substrate.

9. The method of claim 7 including forming at least two resonators over the same backside cavity.

10. The method of claim 1 including forming a piezoelectric layer for a plurality of film bulk acoustic resonators on the same substrate using a single film of piezoelectric material.

11. The method of claim 10 including patterning said piezoelectric film, removing portions of the piezoelectric film, and replacing the removed portions with a dielectric material.

12. An integrated circuit comprising:
a substrate;
a plurality of film bulk acoustic resonators formed on said substrate; and
a plurality of series connected film bulk acoustic resonators coupled by a shunt film bulk acoustic resonator.

13. The circuit of claim 12 including a single backside cavity under said resonators.

14. The circuit of claim 13 including a plurality of strengthening strips extending across said cavity.

15. The circuit of claim 14 wherein said strengthening strips are formed of ion implanted substrate material.

16. The circuit of claim 14 including a pair of parallel strengthening strips.

17. The circuit of claim 12 wherein each of said resonators includes an upper electrode, the upper electrodes of said resonators being co-planar.

18. A film bulk acoustic resonator filter comprising:
a substrate;
a plurality of series connected film bulk acoustic resonators formed on said substrate and at least one shunt connected film bulk acoustic resonator formed on said substrate; and
at least one strengthening strip extending across said substrate.

19. The filter of claim 18 wherein said strip is formed of ion implanted silicon.

20. The filter of claim 18 including at least two parallel strips extending across said substrate.

21. The filter of claim 18 wherein said substrate includes a front side on which said resonators are formed and a backside, a backside cavity being formed in said substrate backside, said strengthening strips being located in said backside cavity.

22. The filter of claim 21 wherein said resonators are formed over the same backside cavity.

23. The filter of claim 22 wherein each of said resonators includes a lower and upper electrode and a piezoelectric film between said electrodes.

24. The filter of claim 23 wherein two adjacent resonators are coupled on a thin upper electrode.

25. The filter of claim 24 wherein two adjacent resonators are coupled via their lower electrodes.
